(19) United States
(12) Patent Application Publication
(10) Pub. No.: US 2008/0293220 A1
(43) Pub. Date: Nov. 27, 2008

(54) Wafer dividing method

(75) Inventor: Masaru Nakamura, Tokyo (JP)

Correspondence Address: SMITH, GAMBRELL & RUSSELL, 1130 CONNECTICUT AVENUE, N.W., SUITE 1130, WASHINGTON, DC, 20036, US

(73) Assignee: Disco Corporation

(21) Appl. No.: 11/889,024

(22) Filed: Aug. 8, 2007

(30) Foreign Application Priority Data
Aug. 10, 2006 (JP) 2006-217726

(51) Int. Cl. H01L 21/302

(52) U.S. Cl. 438/463; 257/E21.214

(57) ABSTRACT

A method of dividing a wafer having a plurality of dividing lines which are formed in a lattice pattern on the front surface, into individual chips along the dividing lines, the method comprising a wafer affixing step for affixing the front surface of the wafer to the front surface of a holding plate having stiffness through an adherent layer; a grinding step for grinding the rear surface of the wafer affixed to the holding plate to a predetermined thickness; a deteriorated layer forming step for applying a pulse laser beam of a wavelength having permeability for the wafer from the rear surface of the wafer which is affixed to the holding plate and has undergone the grinding step to form a deteriorated layer in the inside of the wafer along the dividing lines; a wafer transfer step for putting the rear surface of the wafer which has undergone the deteriorated layer forming step on an adherent tape mounted on an annular frame and removing the holding plate from the front surface of the wafer; and a wafer dividing step for exerting external force to the wafer put on the adherent tape to divide the wafer along the dividing lines.

### FIELD OF THE INVENTION

The present invention relates to a method of dividing a wafer having a plurality of dividing lines which are formed in a lattice pattern on the front surface and devices which are formed in a plurality of areas sectioned by the plurality of dividing lines, into individual chips along the dividing lines.

### DESCRIPTION OF THE PRIOR ART

In the production process of a semiconductor device, a plurality of areas are sectioned by dividing lines called “streets” arranged in a lattice pattern on the front surface of a substantially disk-like semiconductor wafer, and a device such as IC, LSI or the like is formed in each of the sectioned areas. Individual semiconductor chips are manufactured by cutting this semiconductor wafer along the dividing lines to divide it into the areas each having a device formed thereon.

Cutting along the dividing lines of a wafer such as the above semiconductor wafer is generally carried out by using a cutting machine called “dicer”. This cutting machine comprises a chuck table for holding a workpiece such as a semiconductor wafer or an optical device wafer, a cutting means for cutting the workpiece held on the chuck table, and a cutting-feed means for moving the chuck table and the cutting means relative to each other. The cutting means comprises a rotary spindle, a cutting blade mounted onto the spindle and a drive mechanism for rotary-driving the rotary spindle. The cutting blade comprises a disk-like base and an annular cutting-edge which is mounted on the side wall outer peripheral portion of the base and formed as thick as about 20 μm by fixing diamond abrasive grains having a diameter of about 3 μm to the base by electroforming. Since the cutting blade has a thickness of about 20 μm, the dividing lines for sectioning chips must have a width of about 50 μm, whereby the area ratio of the dividing lines to the wafer becomes high, thereby producing a problem in reducing productivity.

As a means of dividing a plate-like workpiece such as a semiconductor wafer, a laser processing method for applying a pulse laser beam of a wavelength having permeability for the workpiece with its focal point set to the inside of the area to be divided is also attempted nowadays and disclosed by Japanese Patent No. 3408805. In the dividing method making use of this laser processing technique, the workpiece is divided by applying a pulse laser beam of a wavelength having permeability for the workpiece from one surface side of the workpiece with its focal point set to the inside to continuously form a deteriorated layer in the inside of the workpiece along the dividing lines and exerting external force along the dividing lines whose strength has been reduced by the formation of the deteriorated layers.

Before the deteriorated layer is formed in the inside of the wafer along the dividing lines by applying a pulse laser beam of a wavelength having permeability for the wafer from one surface side of the wafer with its focal point set to the inside, the rear surface of the wafer is ground to a predetermined finish thickness. Due to the downsizing of an apparatus mounting with a semiconductor chip, it is desired that the chip be as thin as 100 μm or less. When the wafer is ground to a thickness of 100 μm or less, the undulation of the wafer occurs, whereby even when a pulse laser beam is applied from one surface side of the wafer with its focal point set to the inside, it is difficult to form a continuous deteriorated layer accurately in the intermediate portion in the thickness direction of the wafer.

### SUMMARY OF THE INVENTION

It is an object of the present invention to provide a wafer dividing method comprising forming a continuous deteriorated layer in the intermediate portion in the thickness direction of a wafer along dividing lines even when the wafer is made thin, thereby making it possible to accurately divide the wafer into individual chips along the dividing lines where the deteriorated layer has been formed.

To attain the above object, according to the present invention, there is provided a method of dividing a wafer having a plurality of dividing lines which are formed in a lattice pattern on the front surface and devices which are formed in a plurality of areas sectioned by the plurality of dividing lines, into individual chips along the dividing lines, the method comprising:

a wafer affixing step for affixing the front surface of the wafer to the front surface of a holding plate having stiffness through an adherent layer;

a grinding step for holding the holding plate affixed to the wafer on the chuck table of a grinding machine to grind the rear surface of the wafer to a predetermined thickness;

a deteriorated layer forming step for holding the holding plate affixed to the wafer which has undergone the grinding step, on the chuck table of a laser beam processing machine and applying a pulse laser beam of a wavelength having permeability for the wafer from the rear surface of the wafer with its focal point set to the inside of the wafer, to form a deteriorated layer in the inside of the wafer along the dividing lines;

a wafer transfer step for putting the rear surface of the wafer which has undergone the deteriorated layer forming step, on an adherent tape mounted on an annular frame and removing the holding plate from the front surface of the wafer; and

a wafer dividing step for exerting external force to the wafer put on the adherent tape mounted on the annular frame to divide the wafer along the dividing lines where the deteriorated layer has been formed.

The above adherent layer formed on the front surface of the holding plate is made of an adhesive whose adhesive force is reduced by an external stimulus, and an external stimulus imparting step for imparting an external stimulus to the adherent layer is carried out in the wafer transfer step.

According to the present invention, since the front surface of the wafer is affixed to the holding plate having stiffness through the adherent layer before the rear surface of the wafer is ground to a predetermined thickness in the grinding step, even when the thickness of the wafer is reduced to 100 μm or less in the grinding step, undulation does not occur. Since the above deteriorated layer forming step is carried out in a state where the wafer which has undergone the grinding step is affixed to the holding plate, the continuous deteriorated layer can be formed accurately in the intermediate portion in the thickness direction of the wafer along the dividing lines. Therefore, by exerting external force to the wafer, the wafer can be divided accurately along the dividing lines where the deteriorated layer has been formed.

### BRIEF DESCRIPTION OF THE DRAWINGS

FIG. 1 is a perspective view of a semiconductor wafer as a wafer to be divided by the wafer dividing method of the present invention;

FIGS. 2(a) and 2(b) are explanatory diagrams of the wafer affixing step in the wafer dividing method of the present invention;

FIG. 3 is an explanatory diagram of the grinding step in the wafer dividing method of the present invention;

FIG. 4 is a perspective view of the principal portion of a laser beam processing machine for carrying out the deteriorated layer forming step in the wafer dividing method of the present invention;

FIGS. 5(a) and 5(b) are explanatory diagrams of the deteriorated layer forming step in the wafer dividing method of the present invention;

FIGS. 6(a), 6(b) and 6(c) are explanatory diagrams of the wafer transfer step in the wafer dividing method of the present invention;

FIG. 7 is a perspective view of a tape expanding apparatus for carrying out the wafer dividing step in the wafer dividing method of the present invention; and

FIGS. 8(a) and 8(b) are explanatory diagrams of the wafer dividing step in the wafer dividing method of the present invention.

### DETAILED DESCRIPTION OF THE PREFERRED EMBODIMENT

A preferred embodiment of the present invention will be described in detail hereinunder with reference to the accompanying drawings.

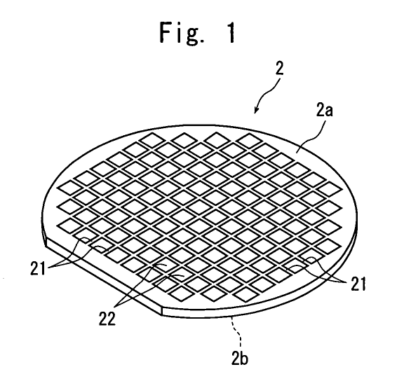

FIG. 1 is a perspective view of a semiconductor wafer as a wafer to be divided by the wafer dividing method of the present invention. The semiconductor wafer 2 shown in FIG. 1 is, for example, a silicon wafer having a thickness of 700 μm, and a plurality of dividing lines 21 are formed in a lattice pattern on the front surface 2a. A device 22 is formed in a plurality of areas sectioned by the plurality of dividing lines 21 on the front surface 2a of the semiconductor wafer 2. The method of dividing this semiconductor wafer 2 into individual semiconductor chips along the plurality of dividing lines 21 will be described hereinunder.

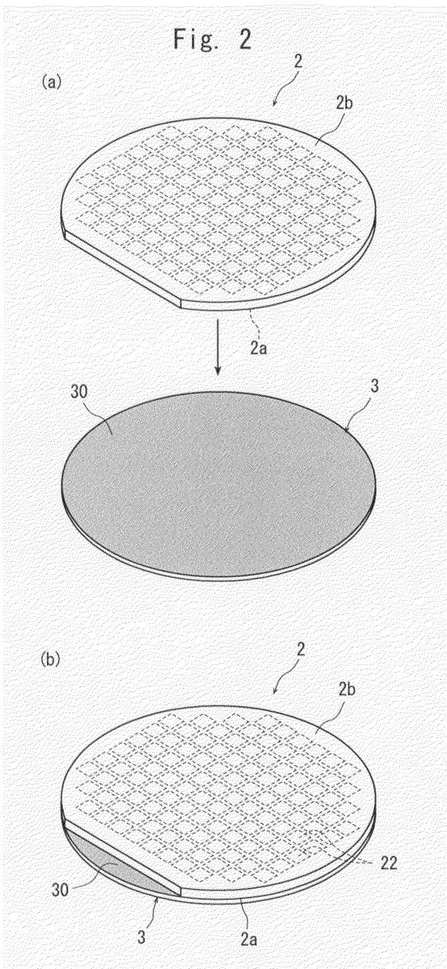

As shown in FIGS. 2(a) and 2(b), first comes the step of affixing the front surface 2a of the semiconductor wafer 2 to the front surface of a holding plate 3 having stiffness through an adherent layer 30. The holding plate 3 is a glass plate or a synthetic resin plate made of polyethylene terephthalate (PET) or the like having a thickness of 0.3 mm or more and has, on the front surface, the adherent layer 30 made of an adhesive whose adhesive force is reduced by the application of an external stimulus such as ultraviolet radiation, etc. Adhesives disclosed by JP-A 2003-151940 and JP-A 2004-296839 may be used as the adhesive whose adhesive force is reduced by the application of an external stimulus such as ultraviolet radiation, etc. The front surface 2a of the semiconductor wafer 2 is affixed to the holding plate 3 through the adherent layer 30 formed on the front surface of the holding plate 3 as described above. Therefore, the rear surface 2b of the semiconductor wafer 2 faces up.

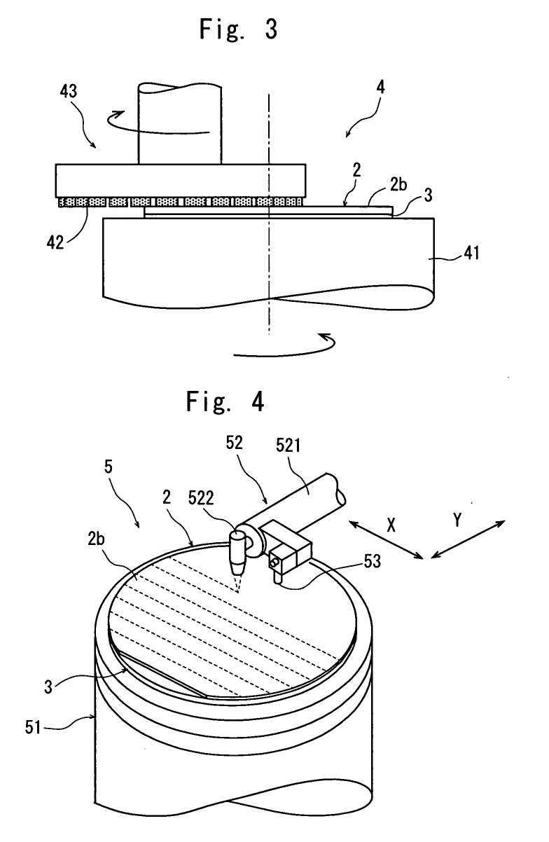

After the above wafer affixing step, next comes the step of grinding the rear surface 2b of the semiconductor wafer 2 affixed to the holding plate 3 through the adherent layer 30 to a predetermined thickness. As shown in FIG. 3, this grinding step is carried out by using a grinding machine 4 which comprises a chuck table 41 for holding a workpiece and a grinding means 43 having a grindstone 42 for grinding the workpiece held on the chuck table 41. That is, the holding plate 3 affixed to the semiconductor wafer 2 is placed on the chuck table 41, and the semiconductor wafer 2 is suction-held on the chuck table 41 through the holding plate 3. Therefore, the rear surface 2b of the semiconductor wafer 2 faces up. After the semiconductor wafer 2 is held on the chuck table 41 through the holding plate 3, the grindstone 42 of the grinding means 43 is rotated at, for example, 6,000 rpm and brought into contact with the rear surface 2b of the semiconductor wafer 2 while the chuck table 41 is rotated at, for example, 300 rpm to reduce the thickness of the semiconductor wafer 2 to 50 μm. Although the thickness of the semiconductor wafer 2 is reduced to 50 μm in this grinding step, as its front surface 2a is affixed to the holding plate 3 having stiffness, undulation does not occur.

The above grinding step is followed by the step of forming a deteriorated layer in the inside of the semiconductor wafer 2 along the dividing lines 21 by applying a pulse laser beam of a wavelength having permeability for the wafer from the rear surface 2b of the semiconductor wafer 2 with its focal point set to the inside of the wafer. This deteriorated layer forming step is carried out by using a laser beam processing machine 5 shown in FIG. 4. The laser beam processing machine 5 shown in FIG. 4 comprises a chuck table 51 for holding a workpiece and a laser beam application means 52 for applying a laser beam to the workpiece held on the chuck table 51. The chuck table 51 is designed to suction-hold the workpiece and moved in a processing-feed direction indicated by an arrow X in FIG. 4 by a processing-feed mechanism (not shown) and an indexing-feed direction indicated by an arrow Y by an indexing-feed mechanism that is not shown. The above laser beam application means 52 applies a pulse laser beam from a condenser 522 mounted onto the end of a cylindrical casing 521 arranged substantially horizontally. The illustrated laser beam processing machine 5 comprises an image pick-up means 53 mounted to the end portion of the casing 521 constituting the above laser beam application means 52. This image pick-up means 53 comprises an infrared illuminating means for applying infrared radiation to the workpiece, an optical system for capturing infrared radiation applied by the infrared illuminating means, and an image pick-up device (infrared CCD) for outputting an electric signal corresponding to infrared radiation captured by the optical system, in addition to an ordinary image pick-up device (CCD) for picking up an image with visible radiation. An image signal is supplied to a control means that is not shown.

To carry out this deteriorated layer forming step by using the laser beam processing machine 5 shown in FIG. 4, the holding plate 3 affixed to the semiconductor wafer 2 which has undergone the above grinding step is first placed on the chuck table 51 and suction-held on the chuck table 51 through the holding plate 3. Therefore, the rear surface 2b of the semiconductor wafer 2 faces up. The chuck table 51 suction-holding the semiconductor wafer 2 is brought to a position right below the image pick-up means 53 by a moving mechanism that is not shown.

After the chuck table 51 is positioned right below the image pick-up means 53, alignment work for detecting the area to be processed of the semiconductor wafer 2 is carried out by the image pick-up means 53 and the control means that is not shown. That is, the image pick-up means 53 and the control means (not shown) carry out image processing such as pattern matching, etc. to align a dividing line 21 formed in a predetermined direction of the semiconductor wafer 2 with the condenser 552 of the laser beam application means 52 for applying a laser beam along the dividing line 21, thereby performing the alignment of a laser beam application position. The alignment of the laser beam application position is also carried out on dividing lines 21 formed on the semiconductor wafer 2 in a direction perpendicular to the above predetermined direction. Although the front surface 2a on which dividing line 21 of the semiconductor wafer 2 is formed faces down at this point, as the image pick-up means 53 comprises the infrared illuminating means, an optical system for capturing infrared radiation and an image pick-up device (infrared CCD) for outputting an electric signal corresponding to the infrared radiation as described above, an image of the dividing line 21 can be picked up through the rear surface 2b.

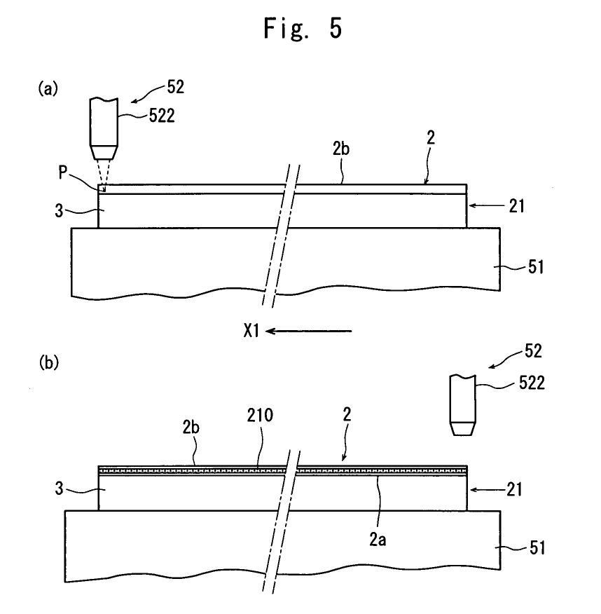

After the alignment of the laser beam application position is carried out by detecting the dividing line 21 formed on the semiconductor wafer 2 held on the chuck table 51 as described above, the chuck table 51 is moved to a laser beam application area where the condenser 552 of the laser beam application means 52 for applying a laser beam is located as shown in FIG. 5(a) so as to bring one end (left end in FIG. 5(a)) of the predetermined dividing line 21 to a position right below the condenser 522 of the laser beam application means 52. The chuck table 51 is then moved in the direction indicated by the arrow X1 in FIG. 5(a) at a predetermined feed rate while a pulse laser beam having permeability for the semiconductor wafer is applied from the condenser 522. When the application position of the condenser 522 of the laser beam application means 52 reaches the other end of the dividing line 21 as shown in FIG. 5(b), the application of the pulse laser beam is suspended and the movement of the chuck table 51 is stopped. In this deteriorated layer forming step, by setting the focal point P of the pulse laser beam to the intermediate portion in the thickness direction of the semiconductor wafer 2, a deteriorated layer 210 is formed in the intermediate portion in the thickness direction of the semiconductor wafer 2 along the dividing line 21. Since undulation does not occur as the front surface of the semiconductor wafer 2 is affixed to the holding plate 3 having stiffness in this deteriorated layer forming step, the continuous deteriorated layer 210 can be formed accurately in the intermediate portion in the thickness direction of the semiconductor wafer 2 along the dividing line 21.

The processing conditions in the above deteriorated layer forming step are set as follows, for example.

Light source: LD excited Q switch Nd:YVO₄ laser

Wavelength: pulse laser having a wavelength of 1,064 nm

Pulse output: 10 μJ

Pulse width: 40 ns

Focal spot diameter: 1 μm

Peak power density of focal point: 3.2×10¹⁰ W/cm²

Repetition frequency: 100 kHz

Processing-feed rate: 100 mm/sec

After the above deteriorated layer forming step is carried out along the predetermined dividing line 21 as described above, the chuck table 51 is moved (indexing-fed) by a distance corresponding to the interval between dividing lines 21 in the direction indicated by the arrow Y in FIG. 4 to carry out the above deteriorated layer forming step. After the above deteriorated layer forming step is carried out along all the dividing lines 21 formed in the predetermined direction of the semiconductor wafer 2, the chuck table 51 is turned at 90° to turn the semiconductor wafer 2 held on the chuck table 51 at 90° so as to carry out the above deteriorated layer forming step along dividing lines 21 formed in a direction perpendicular to the above predetermined direction, whereby the deteriorated layer 210 can be formed in the inside of the semiconductor wafer 2 along all the dividing lines 21.

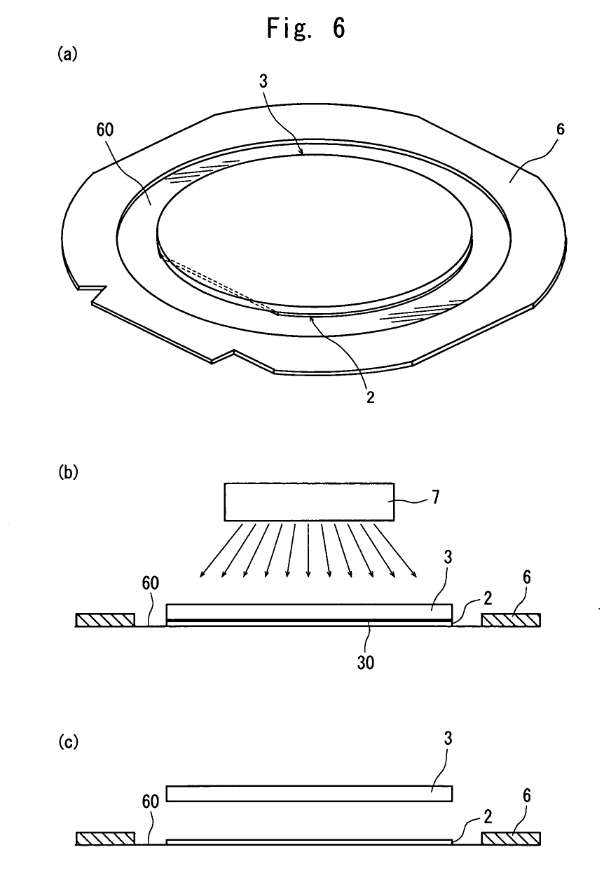

Next comes a wafer transfer step for affixing the rear surface 2b of the semiconductor wafer 2 which has undergone the above deteriorated layer forming step, to an adherent tape mounted on an annular frame to remove the holding plate 3 from the front surface 2a of the semiconductor wafer 2. In this wafer transfer step, the rear surface 2b of the semiconductor wafer 2 is first put on the surface of an adherent tape 60 whose outer peripheral portion is mounted on an annular frame 6 to cover its inner opening, as shown in FIG. 6(a). Therefore, the holding plate 3 side of the semiconductor wafer 2 faces up. The above adherent tape 60 is composed of a sheet material made of polyvinyl chloride (PVC) and having a thickness of 70 μm in the illustrated embodiment. After the rear surface 2b of the semiconductor wafer 2 is put on the surface of the adherent tape 60 mounted on the annular frame 6, ultraviolet radiation is applied to the holding plate 3 from an ultraviolet illuminator 7 as shown in FIG. 6(b) (external stimulus application step). The ultraviolet radiation applied from the ultraviolet illuminator 7 passes through the holding plate 3 which is a glass plate or a polyethylene terephthlate (PET) plate, and is applied to the adherent layer 30. As a result, the adhesive force of the adherent layer 30 is reduced because the adherent layer 30 is made of an adhesive whose adhesive force is reduced by the application of an external stimulus such as ultraviolet radiation as described above. Since the adhesive force of the adherent layer 30 is reduced, as shown in FIG. 6(c), the holding plate 3 can be easily removed from the front surface 2a of the semiconductor wafer 2.

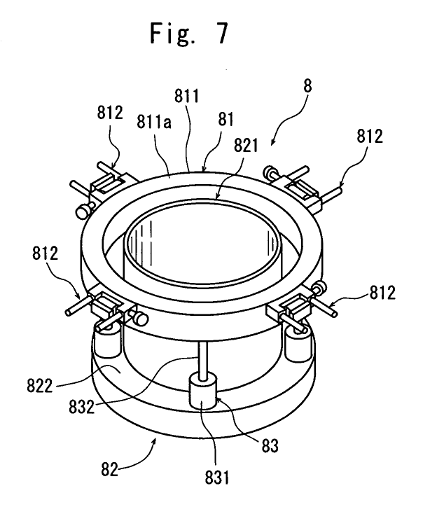

After the above wafer transfer step, next comes a dividing step for dividing the semiconductor wafer 2 affixed to the adherent tape 60 mounted on the annular frame 6 along the dividing lines 21 where the deteriorated layer 210 has been formed by exerting external force to the semiconductor wafer 2. This dividing step is carried out by using a tape expanding apparatus 8 shown in FIG. 7 in the illustrated embodiment. The tape expanding apparatus 8 shown in FIG. 7 comprises a frame holding means 81 for holding the above annular frame 6 and a tape expanding means 82 for expanding the adherent tape 60 mounted on the annular frame 6 held on the frame holding means 81. The frame holding means 81 comprises an annular frame holding member 811 and a plurality of clamps 812 as a fixing means arranged around the frame holding member 811. The top surface of the frame holding member 811 serves as a placing surface 811a for placing the annular frame 6, and the annular frame 6 is placed on the placing surface 811a. The annular frame 6 placed on the placing surface 811a is fixed on the frame holding member 811 by the clamps 812. The frame holding means 81 constituted as described above is supported by the tape expanding means 82 in such a manner that it can move in the vertical direction.

The tape expanding means 82 has an expansion drum 821 installed within the above annular frame holding member 811. This expansion drum 821 has an outer diameter smaller than the inner diameter of the annular frame 6 and an inner diameter larger than the outer diameter of the semiconductor wafer 2 affixed to the adherent tape 60 mounted on the annular frame 6. The expansion drum 821 has a support flange 822 at the lower end. The tape expanding means 82 in the illustrated embodiment has a support means 83 which can move the above annular frame holding member 811 in the vertical direction. This support means 83 comprises a plurality of air cylinders 831 installed on the above support flange 822, and their piston rods 832 are connected to the undersurface of the above annular frame holding member 811. The support means 83 comprising the plurality of air cylinders 831 moves the annular frame holding member 811 in the vertical direction between a standard position where the placing surface 811a becomes substantially flush with the upper end of the expansion drum 821 and an expansion position where the placing surface 811a is positioned below the upper end of the expansion drum 821 by a predetermined distance. Therefore, the support means 83 comprising the plurality of air cylinders 831 functions as an expanding and moving means for moving the expansion drum 821 and the frame holding member 811 relative to each other in the vertical direction.

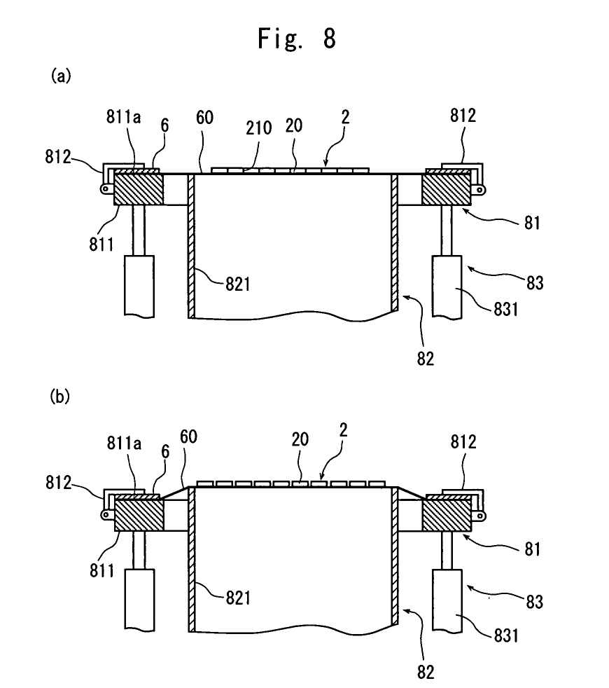

The wafer dividing step which is carried out by using the tape expanding apparatus 8 constituted as described above will be described with reference to FIGS. 8(a) and 8(b). That is, the annular frame 6 mounting the adherent tape 60 affixed to the rear surface 2b of the semiconductor wafer 2 (the deteriorated layer 210 is formed along the dividing lines 21) is placed on the placing surface 811a of the frame holding member 811 of the frame holding means 81 and fixed on the frame holding member 811 by the clamps 812, as shown in FIG. 8(a). At this point, the frame holding member 811 is situated at the standard position shown in FIG. 8(a). The annular frame holding member 811 is then lowered to the expansion position shown in FIG. 8(b) by activating the plurality of air cylinders 831 as the support means 83 constituting the tape expanding means 82. Therefore, the annular frame 6 fixed on the placing surface 811a of the frame holding member 811 is also lowered, whereby the adherent tape 60 mounted on the annular frame 6 comes into contact with the upper edge of the expansion drum 821 to be expanded as shown in FIG. 8(b). As a result, tensile force is applied radially to the semiconductor wafer 2 on the adherent tape 60, whereby the semiconductor wafer 2 is divided into individual semiconductor chips 20 along the dividing lines 21 whose strength has been reduced by the formation of the deteriorated layers 210. The expansion, i.e., elongation of the adherent tape 60 in this wafer dividing step can be adjusted by the downward movement of the frame holding member 811. According to experiments conducted by the inventors of the present invention, when the adherent tape 60 was stretched about 20 mm, the semiconductor wafer 2 could be divided along the dividing lines 21 where the deteriorated layer 210 was formed.

What is claimed is:

1. A method of dividing a wafer having a plurality of dividing lines which are formed in a lattice pattern on the front surface and devices which are formed in a plurality of areas sectioned by the plurality of dividing lines, into individual chips along the dividing lines, the method comprising:
a wafer affixing step for affixing the front surface of the wafer to the front surface of a holding plate having stiffness through an adherent layer;
a grinding step for holding the holding plate affixed to the wafer on the chuck table of a grinding machine to grind the rear surface of the wafer to a predetermined thickness;
a deteriorated layer forming step for holding the holding plate affixed to the wafer which has undergone the grinding step, on the chuck table of a laser beam processing machine and applying a pulse laser beam of a wavelength having permeability for the wafer from the rear surface of the wafer with its focal point set to the inside of the wafer, to form a deteriorated layer in the inside of the wafer along the dividing lines;
a wafer transfer step for putting the rear surface of the wafer which has undergone the deteriorated layer forming step, on an adherent tape mounted on an annular frame and removing the holding plate from the front surface of the wafer; and
a wafer dividing step for exerting external force to the wafer put on the adherent tape mounted on the annular frame to divide the wafer along the dividing lines where the deteriorated layer has been formed.

2. The method according to claim 1, wherein the adherent layer formed on the front surface of the holding plate is made of an adhesive whose adhesive force is reduced by an external stimulus, and an external stimulus imparting step for imparting an external stimulus to the adherent layer is carried out in the wafer transfer step.
